(19) United States
(12) Patent Application Publication
(10) Pub. No.: US 2005/0062162 A1
(43) Pub. Date: Mar. 24, 2005

(54) Pad structure of semiconductor device for reducing or inhibiting wire bonding cracks

(76) Inventors: Yu-Jen Shen, Sanchong City (TW); Chin-Pen Yeh, Hsinchu City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 10/668,985

(22) Filed: Sep. 22, 2003

(51) Int. Cl. H01L 23/48

(52) U.S. Cl. 257/758

(57) ABSTRACT

A pad structure of semiconductor device have a special via pattern to divide the IMD layer into separated IMD blocks, so that the wire bonding cracks are reduced or completely inhibited. According to the invention, the pad structure with a single via pattern of the invention does effectively reduce the wire bonding cracks, and the pad structure with two layers of special via patterns of the invention does completely inhibit the wire bonding cracks.

### BACKGROUND OF THE INVENTION

1. Field of the Invention

The invention relates in general to a pad structure of semiconductor device, and more particularly to an improved pad structure of semiconductor device for reducing wire bonding cracks.

2. Description of the Related Art

Light, small and easy to carry electronic product is a leading trend of modern living. Chip-On-Board (COB) technology has become one of common technique in the fabrication of modern electronic product, and wire bonding and molding procedures are the key steps in COB technique. Generally, COB technology consists of three semiconductor die to printed circuit board conductive attachment techniques: wire bonding, flip chip attachment and tape automated bonding (TAB).

The bond wires are generally attached through one of three industry-standard wire bonding techniques: ultrasonic bonding—using a combination of pressure and ultrasonic vibration bursts to form a metallurgical cold weld; thermocompression bonding—using a combination of pressure and elevated temperature to form a weld; and thermosonic bonding—using a combination of pressure, elevated temperature, and ultrasonic vibration bursts.

Thus, as the semiconductor device is subjected to the normal stresses of subsequent forming and assembly operations (such as bonding pressure), parts of device structure may crack, especially the interface between VIA window and Inter-metal dielectric layer (IMD).

FIG. 1A is a cross-sectional view of a portion of a conventional semiconductor device. In order to clarify the technical differences between the prior art and the invention, the drawings in the context of the invention only show the major characteristic parts of the semiconductor device. Beneath the metallic layers, the semiconductor device 100 comprises a silicon substrate 102, a field oxide layer 104 and an inter-layer dielectrics 106, as shown in FIG. 1A. The silicon substrate 100 has a p-well region or/and an n-well region beneath (not shown); for example, a p-well is formed by diffusion or ion implantation of boron into the silicon substrate 102, as well known in the art. A complete integrated circuit (IC) device consists of numerous MOS transistor. Several dielectric layers should be formed in the IC device for the purpose of isolation; for example, the field oxide (commonly termed “FOX”) layer 104 is used for the isolation of the adjacent transistors, and the inter-layer dielectric (commonly termed “ILD”) layer 106 is used for the isolation between the metallic layer and the substrate 102. Borophosphosilicate glass (BPSG) is typically used as the material of the ILD layer 106, and can be formed over the substrate 102 and the FOX layer 104 by thermal chemical vapor deposition (CVD) process, as known in the art. Subsequently, the metallic layer deposition is performed.

Single or multi metallic layers can be deposited above the ILD layer 106, depending on the requirement of semiconductor device. In FIG. 1A, three metallic layers, including the first metallic layer 108, the second metallic layer 114 and the third metallic layer 120, are taken for illustration. Also, an inter-metal dielectric (commonly termed “IMD”) layer and several via holes are formed between two metallic layers. Those via holes are typically filled with metal such as tungsten (W).

According to the illustration of FIG. 1, there are a first IMD layer 110 and several first via holes 112 formed between the first metallic layer 108 and the second metallic layer 114. A second IMD layer 116 and several second via holes 118 are formed between the second metallic layer 114 and the third metallic layer 120. All of the first via holes 112 and second via holes 118 are filled with tungsten (W), to contact the associated metallic layers both mechanically and electrically. Silicon oxides (SiO₂) is a typical material of the first IMD layer 110 and the second IMD layer 116, and can be formed by plasma-enhanced chemical vapor deposition (PECVD), or high-density-plasma chemical vapor deposition (HDP-CVD) process.

FIG. 1B is a top view of the IMD layer and via holes of FIG. 1A. FIG. 1C is a diagrammatic oblique view of the second via holes of FIG. 1A after wire bonding. The arrangement of the second via holes 118 in the second IMD layer 116 is like the pins sticking into the pincushion, as shown in FIG. 1B and FIG. 1C. Because the material (such as silicon oxide) of the second IMD layer 116 is much more fragile than metal such as tungsten filled in the via holes 118, the interface between the IMD and metal is easily broken under the wire-bonding pressure. Those cracks 171, 172, and 173 as shown in FIG. 1C are so-called “pad cracks”.

Also, since the conventional via holes are arranged like the pins in the pincushion, the IMD layer interposed between two metallic layers can be treated as a continuous substance. The crack generated under the bonding pressure is free to extend until it hits the interface between the IMD and via contact (via hole filled with tungsten). Thus, the unstoppable cracks, such as the longer cracks 171 and 173 of FIG. 1C, are the typical problem when wire bonding the semiconductor device with the conventional pad structure. If an IC chip having the pad crack defect is installed in the electronic product, some problems, for example, current leakage, occur as expected.

### SUMMARY OF THE INVENTION

It is therefore an object of the invention to provide a pad structure of semiconductor device with a special via pattern, so as to reduce or completely inhibit the wire bonding cracks.

The invention achieves the first objects by providing a pad structure of semiconductor device for reducing wire bonding crack. The device comprises a substrate; an inter-layer dielectric (ILD) layer formed over the substrate; a plurality of metallic layers formed over the ILD layer; and a plurality of inter-metal dielectric (IMD) layers. Each IMD layer is formed between two metallic layers, and has a plurality of via holes. At least one of IMD layers is divided into a plurality of separated IMD blocks by the via holes formed therein, which the via holes contact one metallic layer closest to a pad bonding layer.

The invention achieves the second first objects by providing a pad structure of semiconductor device for completely inhibiting wire bonding crack. The device comprises a substrate; an inter-layer dielectric (ILD) layer formed over the substrate; a plurality of metallic layers formed over the ILD layer; and a plurality of inter-metal dielectric (IMD) layers. Each IMD layer is formed between two metallic layers, and has a plurality of via holes. At least two of IMD layers are divided into a plurality of separated IMD blocks by the via holes formed therein. Also, one of at least two IMD layer is preferably close to a pad bonding layer.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1A (prior art) is a cross-sectional view of a portion of a conventional semiconductor device;

FIG. 1B (prior art) is a top view of the IMD layer and via holes of FIG. 1A;

FIG. 1C (prior art) is a diagrammatic oblique view of the second via holes of FIG. 1A after wire bonding;

FIG. 2 is a diagrammatic oblique view of a portion of a semiconductor device in accordance with the first embodiment of the invention;

FIG. 3 is a diagrammatic oblique view of a portion of a semiconductor device in accordance with the second embodiment of the invention; and

FIG. 4A˜FIG. 4L are the top views of the via holes of Pat. 1˜Pat. 12 in Experiments 2 and 3, respectively.

### DETAILED DESCRIPTION OF THE INVENTION

In the present invention, the inter-metal dielectric (IMD) layer is divided into several individual IMB blocks by a special via pattern, in order to reduce or completely inhibit the wire-bonding crack phenomenon. The details of the invention are described by two embodiments. In the first embodiment, a single IMD layer with a special via (hole) pattern is constructed to reduce the wire-bonding cracks. In the second embodiment, two IMD layers with a special via (hole) pattern in each are constructed to inhibit the wire-bonding cracks.

Also, the drawings used for illustrating the embodiment of the invention only show the major characteristic parts of the semiconductor device in order to avoid obscuring the invention. Accordingly, the specification and the drawing are to be regard as an illustrative sense rather than a restrictive sense.

### First Embodiment

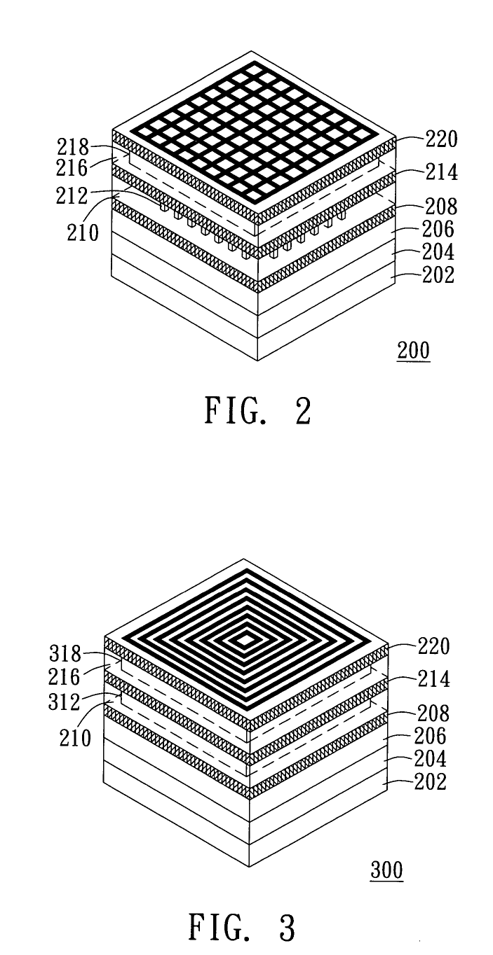

FIG. 2 is a diagrammatic oblique view of a portion of a semiconductor device in accordance with the first embodiment of the invention. Beneath the metallic layers, the semiconductor device 200 comprises a silicon substrate 202, a field oxide layer 204 and an inter-layer dielectrics 206. The silicon substrate 200 has a p-well region or/and an n-well region beneath (not shown); for example, a p-well is formed by diffusion or ion implantation of boron into the silicon substrate 202, as well known in the art. The field oxide (commonly termed “FOX”) layer 204 is used for the isolation of the adjacent transistors (not shown), and the inter-layer dielectric (commonly termed “ILD”) layer 206 is used for the isolation between the metallic layer and the substrate 202. Borophosphosilicate glass (BPSG) is a typical material of the ILD layer 206, and can be formed over the substrate 202 and the FOX layer 204 by thermal chemical vapor deposition (CVD) process. Subsequently, the metallic layer deposition is performed.

Single or multi metallic layers can be deposited above the ILD layer 206, depending on the requirement of semiconductor device. In the first embodiment, three metallic layers, including the first metallic layer 208, the second metallic layer 214 and the third metallic layer 220, are used for illustration. Also, an inter-metal dielectric (commonly termed “IMD”) layer and several via holes are further formed between two metallic layers. Those via holes are typically filled with metal such as tungsten (W).

In FIG. 2, a first IMD layer 210 and several first via holes 212 are formed between the first metallic layer 208 and the second metallic layer 214. A second IMD layer 216 and several second via holes 218 are formed between the second metallic layer 214 and the third metallic layer 220. All of the first via holes 212 and second via holes 218 are filled with tungsten (W), in order to contact the associated metallic layers both mechanically and electrically. Silicon oxides (SiO₂) is a typical material of the first IMD layer 210 and the second IMD layer 216, and can be formed by plasma-enhanced chemical vapor deposition (PECVD), or high-density-plasma chemical vapor deposition (HDP-CVD) process.

In the first embodiment, only one IMD layer having a special via pattern is constructed to reduce the wire bonding cracks. This “special” IMD layer is preferably at the position close to the bonding pads, for effectively buffering the impact of a bonding force (the closer, the better). In FIG. 2, the second IMD layer 216 is the “special” IMD layer of the invention, and the second via holes 218 compose a special via pattern.

As shown in FIG. 2, the top surfaces of the second via holes 218 compose a chessboard pattern, and the second IMD layer 216 is divided into a plurality of separated IMD blocks by the second via holes 218. It has been proved (see Experiment 2) that those separated IMD blocks can effectively stop the cracks from wild extension after impacted by the bonding force, even the cracks occur at the interface between the second via hole (filled with W) 218 and the IMD layer (SiO₂) 216.

It is noted that the special via pattern is not limited to the chessboard pattern as shown in FIG. 2, it could be any patterns which can turn the IMD layer into several individual IMD blocks, such as a pattern in a form of concentric frames, concentric circles, or spider web.

### Second Embodiment

In the second embodiment, two IMD layers with a special via (hole) pattern in each are constructed. It has been proved (see Experiment 3) that those separated IMD blocks of two IMD layers can completely inhibit the wire bonding cracks.

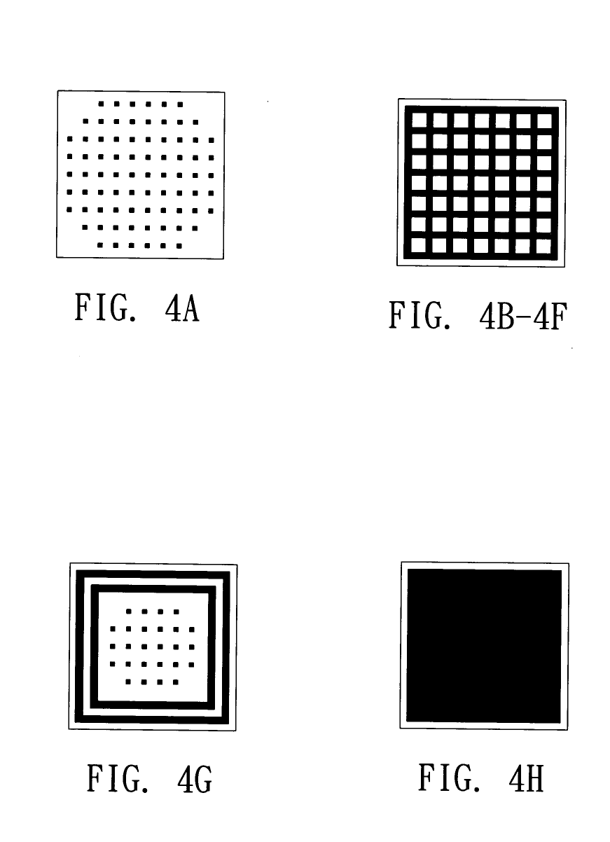

FIG. 3 is a diagrammatic oblique view of a portion of a semiconductor device in accordance with the second embodiment of the invention. Components common to FIG. 2 retain the same numeric designation. Beneath the metallic layers, the semiconductor device 300 comprises a silicon substrate 202, a field oxide (commonly termed “FOX”) layer 204 and an inter-layer dielectrics 206. Borophosphosilicate glass (BPSG) is a typical material of the ILD layer 206, and can be formed over the substrate 202 and the FOX layer 204 by thermal chemical vapor deposition (CVD) process. Single or multi metallic layers can be deposited above the ILD layer 206, depending on the requirement of semiconductor device. In the second embodiment, three metallic layers, including the first metallic layer 208, the second metallic layer 214 and the third metallic layer 220, are used for illustration.

Also, a first IMD layer 210 and several first via holes 312 are formed between the first metallic layer 208 and the second metallic layer 214. A second IMD layer 216 and several second via holes 318 are formed between the second metallic layer 214 and the third metallic layer 220. All of the first via holes 312 and second via holes 318 are filled with tungsten (W), in order to contact the associated metallic layers both mechanically and electrically. Silicon oxides (SiO₂) is a typical material of the first IMD layer 210 and the second IMD layer 216, and can be formed by plasma-enhanced chemical vapor deposition (PECVD), or high-density-plasma chemical vapor deposition (HDP-CVD) process.

In the second embodiment, two IMD layers both having the special via pattern is constructed to inhibit the wire bonding cracks. Those individual IMD blocks of the first and second IMD layers do increase the stress area, and consequently decrease the wire-bonding stress applied to IMD layer. Also, the results of the wire bonding experiment (Experiment 3) indicate that the device structure according to the second embodiment of the invention is capable of inhibiting the wire bonding cracks.

It is noted that the special via pattern is not limited to the concentric frames as shown in FIG. 3, it could be any patterns which can divide the IMD layer into several individual IMD blocks, such as a pattern in a form of chessboard, concentric circles, or spider web.

It is, of course, understood that a number of configuration of this embodiment could be constructed, including stacks of more than two IMD layers having individual IMD blocks, or stacks of more than three metallic layers. Those “special” IMD layers are preferably at the positions close to the bonding pads, for completely buffering the impact of a bonding force (the closer, the better).

Moreover, the first via pattern (formed by the top surfaces of the first via holes 312) could be, or could be not identical with the second via pattern (formed by the top surfaces of the first via holes 318). Also, the individual IMD blocks of the first and second IMD layer could be aligned, or staggered with each other.

### Wire Bonding Experiment

Experiment 1: Two IMD Layers Having Pin-Like Via Holes (Comparative Exp.)

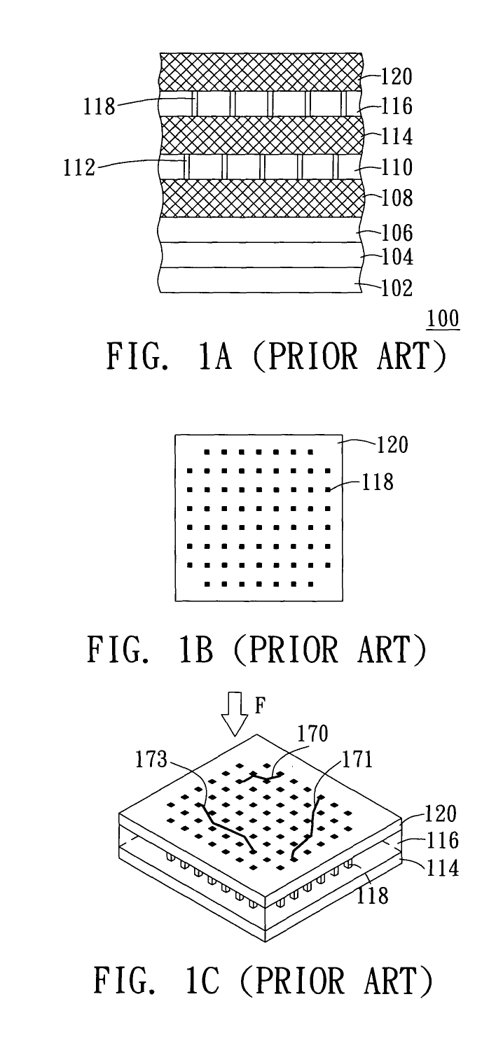

A wire bonding experiment of conventional pad structure having VIA 1 STD/VIA 2 STD (i.e. the first via holes arranged in the standard pin-like form/the second via holes arranged in the standard pin-like form) is conducted for comparison. Please also refer to FIG. 1A˜FIG. 1C for the demonstration of pad structure of Experiment 1. In Experiment 1, it is investigated if altering the wire boding parameters has an effect on the reduction of the wire bonding cracks. The results are summarized in Table 1.

The results of Table 1 indicated that more cracks occurred while increase the bonding power. Although less cracks were observed while decreasing the bonding power, the device fails in wire pull test. Accordingly, altering the wire boding parameters has no substantial effect on the reduction of the wire bonding cracks.

Experiment 2: One IMD Layer Having a Via Pattern of the Invention

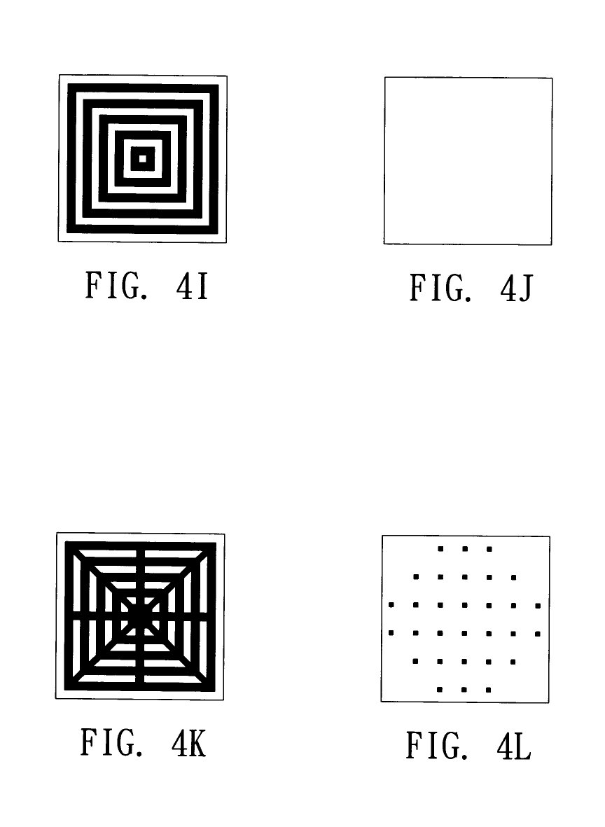

A wire bonding experiment of a pad structure having VIA 1 STD/VIA 2 experimental pattern (i.e. the first via holes arranged in the standard pin-like form/the second via holes arranged in a special pattern of the invention) is conducted. Please also refer to FIG. 2 for the demonstration of pad structure of Experiment 2. In Experiment 2, it is investigated if a single IMD layer with several individual IMD blocks has an effect on the reduction of the wire bonding cracks. The results are summarized in Table 2. The top view of the via patterns are depicted in FIG. 4A˜FIG. 4L, respectively. In FIG. 4A˜FIG. 4L, the dark area represents the top view of the via holes filled with tungsten, and the empty area with no marking represents the top view of the IMD layer. Also, the top view of the via holes of sample no. Pat. 2˜Pat. 6 (FIG. 4B˜FIG. 4F) are all in a form of chessboard, except the widths of the via and IMD block are different.

The results of Table 2 indicated that the pad structure with a single via pattern does effectively reduce the wire bonding cracks.

Experiment 3: Two IMD Layers Both Having a Via Pattern of the Invention

A wire bonding experiment of a pad structure having VIA 1 experimental pattern/VIA 2 experimental pattern (i.e. the first via holes and the second via holes all arranged in a special pattern of the invention) is conducted. In this experiment, the VIA 1 pattern is identical with the VIA 2 pattern. Please also refer to FIG. 3 for the demonstration of pad structure of Experiment 3. It is investigated if two IMD layers with several individual IMD blocks have an effect on the completely inhibition of the wire bonding cracks herein. The results are summarized in Table 3. Also, the top view of the via patterns are depicted in FIG. 4A˜FIG. 4L, respectively. In FIG. 4A˜FIG. 4L, the dark area represents the top view of the via holes filled with tungsten, and the empty area with no marking represents the top view of the IMD layer. The top view of the via holes of Pat. 2˜Pat. 6 (FIG. 4B˜FIG. 4F) are all in the chessboard-like form, except the widths of the via and IMD block are different.

The vias having the top surfaces of Pat. 2, Pat. 3, Pat. 5, Pat. 6, Pat. 9 and Pat. 11 can divide the IMD layer into several individual IMD blocks, and successfully pass the bonding examine without peeling and cracking. Accordingly, the results of Table 3 indicated that the pad structure with two layers of special via patterns of the invention does completely inhibit the wire bonding cracks.

In the aforementioned description, the via with a special pattern which divides the IMD layer into several individual IMD blocks could restrict the crack path from wild spread, and consequently decrease the possibility of crack generation. According to the experimental results, the pad structure with a single via pattern of the invention does effectively reduce the wire bonding cracks, and the pad structure with two layers of special via patterns of the invention does completely inhibit the wire bonding cracks. Consequently, the yield of semiconductor device is greatly increased.

While the invention has been described by way of examples and in terms of the preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

TABLE 1

| | | | | Experimental Results | |
|---|---|---|---|---|---|
| Sample | Wire Bonding Conditions | | | | Wire Pull |
| No. | Power | Force | Time | Cracks | Test |
| 1* | 85 mw | 30 g | 20 ms | Occurred | — |
| 2 | 95 mw | 30 g | 20 ms | Serious | — |
| 3 | 75 mw | 26 g | 20 ms | Occurred | — |
| 4 | 70 mw | 25 g | — | Occurred | Pass |
| 5 | 70 mw | 20 g | — | Occurred | Fail |
| 6 | 60 mw | 25 g | — | Occurred | Fail |
| 7 | 60 mw | 20 g | — | Less | Fail |

*Sample undergoing the standard wire bonding condition (STD parameters)

TABLE 2

| Bonding | Sample No. | | | | | | | | | | | |
|---|---|---|---|---|---|---|---|---|---|---|---|---|
| Conditions | Pat. 1 | Pat. 2 | Pat. 3 | Pat. 4 | Pat. 5 | Pat. 6 | Pat. 7 | Pat. 8 | Pat. 9 | Pat. 10 | Pat. 11 | Pat. 12 |
| 100 mw/30 g | 8/8 | 2/12 | 5/12 | 3/12 | 3/12 | 8/12 | 11/12 | 6/8 | 10/12 | 8/12 | 4/8 | 4/8 |
| | cracked | | | | | | | | | | | |
| 90 mw/30 g | 8/8 | 4/12 | 5/12 | 2/12 | 5/12 | 10/12 | 10/12 | 8/8 | 8/12 | 6/12 | 7/8 | 7/8 |
| 80 mw/30 g* | 8/8 | 0/12 | 0/12 | 0/12 | 0/12 | 6/12 | 10/12 | 6/8 | 4/12 | 4/12 | 4/8 | 2/8 |
| 100 mw/20 g | 8/8 | 7/12 | 6/12 | 4/12 | 8/12 | 9/12 | 12/12 | 6/8 | 11/12 | 12/12 | 6/8 | 8/8 |
| 90 mw/30 g | 6/8 | 6/12 | 6/12 | 1/12 | 3/12 | 8/12 | 11/12 | 6/8 | 12/12 | 10/12 | 7/8 | 7/8 |
| 80 mw/30 g | 4/8 | 1/12 | 5/12 | 2/12 | 1/12 | 4/12 | 11/12 | 5/8 | 11/12 | 10/12 | 4/8 | 5/8 |
| | | | | peeling | | | | peeling | | | | |

Pat. 2: A = 0.6 μm, B = 2 μm;
Pat. 3: A = 1 μm, B = 2 μm;
Pat. 4: A = 2 μm, B = 2 μm;
Pat. 5: A = 0.6 μm, B = 1 μm
Pat. 6: A = 1 μm, B = 1 μm
*standard wire bonding parameters
#/#: (cracked pad numbers)/(total pad numbers)

TABLE 3

| Bonding | SampleNo. | | | | | | | | | | | |
|---|---|---|---|---|---|---|---|---|---|---|---|---|
| Condition | Pat. 1 | Pat. 2 | Pat. 3 | Pat. 4 | Pat. 5 | Pat. 6 | Pat. 7 | Pat. 8 | Pat. 9 | Pat. 10 | Pat. 11 | Pat. 12 |
| 70 mw/30 g | 4/6 | 0/49 | 0/49 | peeling | 0/9 | 0/9 | 0/9 | 4/6 | 0/9 | 5/9 | 0/9 | 2/6 |
| | | | | | | | | peeling | | | | |
| 80 mw/30 g* | 2/6 | 0/49 | 0/49 | | 0/9 | 0/9 | 5/9 | | 0/9 | 6/9 | 0/9 | 0/6 |
| 90 mw/30 g* | 4/6 | 0/49 | 0/49 | | 0/9 | 0/9 | 6/9 | | 0/9 | 5/9 | 0/9 | 0/6 |
| 70 mw/20 g | 3/6 | 0/49 | 0/49 | | 0/9 | 0/9 | 7/9 | | 0/9 | 8/9 | 0/9 | 0/6 |
| 80 mw/20 g | 4/6 | 0/49 | 0/49 | | 0/9 | 0/9 | 5/9 | | 0/9 | 9/9 | 0/9 | 3/6 |
| 90 mw/20 g | 6/6 | 0/49 | 0/49 | | 0/9 | 0/9 | 9/9 | | 0/9 | 9/9 | 0/9 | 3/6 |

Pat. 2: A = 0.6 μm, B = 2 μm;
Pat. 3: A = 1 μm, B = 2 μm;
Pat. 4: A = 2 μm, B = 2 μm;
Pat. 5: A = 0.6 μm, B = 1 μm
Pat. 6: A = 1 μm, B = 1 μm
*standard wire bonding parameters
#/#: (cracked pad numbers)/(total pad numbers)

1. A pad structure of semiconductor device for reducing wire bonding crack, comprising:
a substrate;
an inter-layer dielectric (ILD) layer formed over the substrate;
a first metallic layer formed over the ILD layer;
a second metallic layer formed over the first metallic layer, and a first inter-metal dielectric (IMD) layer formed between the first metallic layer and the second metallic layer, wherein a plurality of first via holes are formed in the first IMD layer; and
a third metallic layer formed over the second metallic layer, and a second inter-metal dielectric (IMD) layer formed between the second metallic layer and the third metallic layer, wherein a plurality of second via holes are formed in the second IMD layer;
wherein the top surfaces of the second via holes compose a special via pattern, and the second IMD layer is divided into a plurality of separated IMD blocks by the second via holes, thereby reducing wire bonding cracks.

2. The pad structure of claim 1, wherein an area proportion between the second via holes and the second IMD layer is larger than that between the first via holes and the first IMD layer.

3. The pad structure of claim 1, wherein the substrate is a silicon substrate.

4. The pad structure of claim 1, wherein the ILD layer is made of borophosphosilicate glass (BPSG).

5. The pad structure of claim 1, wherein a field-oxide layer is further interposed between the substrate and the ILD layer.

6. The pad structure of claim 1, wherein the first IMD layer and the second IMD layer are made of silicon oxide.

7. The pad structure of claim 1, wherein the first via holes and the second via holes are filled with tungsten (W).

8. The pad structure of claim 1, wherein the top surfaces of the second via holes are in a form of chessboard.

9. The pad structure of claim 1, wherein the top surfaces of the second via holes are in a form of concentric frames.

10. The pad structure of claim 1, wherein the top surfaces of the second via holes are in a form of concentric circles.

11. The pad structure of claim 1, wherein the top surfaces of the second via holes are in a form of spider web.

12. A pad structure of semiconductor device for inhibiting wire bonding crack, comprising:
a substrate;
an inter-layer dielectric (ILD) layer formed over the substrate;
a first metallic layer formed over the ILD layer;
a second metallic layer formed over the first metallic layer, and a first inter-metal dielectric (IMD) layer formed between the first metallic layer and the second metallic layer, wherein a plurality of first via holes are formed in the first IMD layer; and
a third metallic layer formed over the second metallic layer, and a second inter-metal dielectric (IMD) layer formed between the second metallic layer and the third metallic layer, wherein a plurality of second via holes are formed in the second IMD layer;
wherein the first IMD layer is divided into a plurality of separated first IMD blocks by the first via holes, and the second IMD layer is divided into a plurality of separated second IMD blocks by the second via holes.

13. The pad structure of claim 12, wherein the second via holes are positioned above and aligned with the first via holes.

14. The pad structure of claim 12, wherein the second via holes are positioned above and staggered from the first via holes.

15. The pad structure of claim 12, wherein top surfaces of the first via holes compose a special first via pattern, and top surfaces of the second via holes compose a special second via pattern.

16. The pad structure of claim 15, wherein the first via pattern is identical with the second via pattern.

17. The pad structure of claim 16, wherein both the first via pattern and the second via pattern are in a form of chessboard.

18. The pad structure of claim 16, wherein both the first via pattern and the second via pattern are in a form of concentric frames.

19. The pad structure of claim 16, wherein both the first via pattern and the second via pattern are in a form of concentric circles.

20. The pad structure of claim 16, wherein both the first via pattern and the second via pattern are in a form of spider web.

21. The pad structure of claim 12, wherein the substrate is a silicon substrate, and the ILD layer is made of borophosphosilicate glass (BPSG).

22. The pad structure of claim 12, wherein a field-oxide layer is further interposed between the substrate and the ILD layer.

23. The pad structure of claim 12, wherein the first IMD layer and the second IMD layer are made of silicon oxide.

24. The pad structure of claim 12, wherein the first via holes and the second via holes are filled with tungsten (W).

25. A pad structure of semiconductor device for reducing wire bonding crack, comprising:
a substrate;
an inter-layer dielectric (ILD) layer formed over the substrate;
a plurality of metallic layers formed over the ILD layer; and
a plurality of inter-metal dielectric (IMD) layers, wherein each IMD layer is formed between two metallic layers, and has a plurality of via holes;
at least one of IMD layers is divided into a plurality of separated IMD blocks by the via holes formed therein, which the via holes contact one metallic layer closest to a pad bonding layer.

26. The pad structure of claim 25, wherein an area proportion between the via holes and the IMD layer with the separated IMD blocks is larger than that without the separated IMD blocks.

27. The pad structure of claim 25, wherein the ILD layer is made of borophosphosilicate glass (BPSG), and a field-oxide layer is further interposed between the substrate and the ILD layer.

28. The pad structure of claim 25, wherein the IMD layers are made of silicon oxide, and the via holes are filled with tungsten (W).

29. The pad structure of claim 25, wherein the top surfaces of the via holes that separate the IMD layer into the IMD blocks compose a special via pattern.

30. The pad structure of claim 29, wherein the special via pattern is in a form of chessboard.

31. The pad structure of claim 29, wherein the special via pattern is in a form of concentric frames.

32. The pad structure of claim 29, wherein the special via pattern is in a form of concentric circles.

33. The pad structure of claim 29, wherein the special via pattern is in a form of spider web.

34. A pad structure of semiconductor device for inhibiting wire bonding crack, comprising:
a substrate;
an inter-layer dielectric (ILD) layer formed over the substrate;
a plurality of metallic layers formed over the ILD layer; and
a plurality of inter-metal dielectric (IMD) layers, wherein each IMD layer is formed between two metallic layers and has a plurality of via holes;
at least two of IMD layers are divided into a plurality of separated IMD blocks by the via holes formed therein.

35. The pad structure of claim 34, wherein a Nth (N≧2, N is a positive integer) IMD layer and a (N−1)th IMD layer are divided into a plurality of separated IMD blocks by a plurality of Nth via holes and (N−1)th via holes, and top surfaces of the Nth via holes and (N−1)th via holes compose a special Nth pattern and a special (N−1) pattern, respectively.

36. The pad structure of claim 35, wherein the Nth via holes are positioned above and aligned with the (N−1)th via holes.

37. The pad structure of claim 35, wherein the n-th via holes are positioned above and staggered from the (N−1)th via holes.

38. The pad structure of claim 35, wherein the Nth via pattern is identical with the (N−1)th via pattern.

39. The pad structure of claim 38, wherein both the Nth via pattern and the (N−1)th via pattern are in a form of chessboard.

40. The pad structure of claim 38, wherein both the Nth via pattern and the (N−1)th via pattern are in a form of concentric frames.

41. The pad structure of claim 38, wherein both the Nth via pattern and the (N−1)th via pattern are in a form of concentric circles.

42. The pad structure of claim 38, wherein both the Nth via pattern and the (N−1)th via pattern are in a form of spider web.

43. The pad structure of claim 34, wherein the ILD layer is made of borophosphosilicate glass (BPSG), and a field-oxide layer is further interposed between the substrate and the ILD layer.

44. The pad structure of claim 34, wherein the IMD layers are made of silicon oxide, and the via holes are filled with tungsten (W).

45. A pad structure of semiconductor device for inhibiting wire bonding crack, comprising:
a substrate;
an inter-layer dielectric (ILD) layer formed over the substrate;
a plurality of metallic layers formed over the ILD layer; and
a plurality of inter-metal dielectric (IMD) layers, wherein each IMD layer is formed between two metallic layers and has a plurality of via holes;
at least two of IMD layers having a plurality of separated IMD blocks, and one of said two IMD layers having the via holes contacting a closest pad bonding layer.

46. The pad structure of claim 45, wherein a value of (via hole)/(IMD) of the IMD layer with the separated IMD blocks is larger than that of the IMD layer without the separated IMD blocks.

47. The pad structure of claim 45, wherein those separated IMD blocks of at least two IMD layers is aligned with each other.

48. The pad structure of claim 45, wherein those separated IMD blocks of at least two IMD layers is staggered from each other.

49. The pad structure of claim 45, wherein top surfaces of the separated IMD blocks of at least two IMD layers compose a first IMD pattern and a second IMD pattern, respectively.

50. The pad structure of claim 49, wherein the first IMD pattern is identical with the second IMD pattern.

51. The pad structure of claim 50, wherein the first IMD pattern as well as the second IMD pattern comprises a plurality of isolated and rectangular IMD blocks.

52. The pad structure of claim 50, wherein the first IMD pattern as well as the second IMD pattern comprises a plurality of isolated and concentric IMD frames.

53. The pad structure of claim 50, wherein the first IMD pattern as well as the second IMD pattern comprises a plurality of isolated and concentric IMD circles.

54. The pad structure of claim 50, wherein the first IMD pattern as well as the second IMD pattern comprises a plurality of isolated and honeycombed IMD blocks.

55. The pad structure of claim 45, wherein the ILD layer is made of borophosphosilicate glass (BPSG), and a field-oxide layer is further interposed between the substrate and the ILD layer.

56. The pad structure of claim 45, wherein the IMD layers are made of silicon oxide, and the via holes are filled with tungsten (W).
